(19) United States
(12) Patent Application Publication
(10) Pub. No.: US 2018/0152154 A1
(43) Pub. Date: May 31, 2018

(54) RADIO FREQUENCY POWER AMPLIFIER AND WIRELESS COMMUNICATIONS DEVICE

(71) Applicant: Samsung Electro-Mechanics Co., Ltd., Swuwon-si (KR)

(72) Inventors: Tadamasa MURAKAMI, Yokohama-City (JP); Tsuyoshi SUGIURA, Yokohama-City (JP); Koki TANJI, Yokohama-City (JP); Norihisa OTANI, Yokohama-City (JP); Satoshi FURUTA, Yokohama-City (JP)

(73) Assignee: Samsung Electro-Mechanics Co., Ltd., Suwon-si (KR)

(21) Appl. No.: 15/823,914

(22) Filed: Nov. 28, 2017

(30) Foreign Application Priority Data
Nov. 29, 2016 (JP) 2016-231488
Nov. 13, 2017 (KR) 10-2017-0150546

(51) Int. Cl. H03F 3/195; H03F 1/02

(52) U.S. Cl. CPC H03F 3/195; H03F 2200/451; H03F 1/0211

(57) ABSTRACT

A radio frequency power amplifier includes: a transistor configured to amplify a signal at a selected signal frequency; a first line connected to an output of the transistor and disposed on a printed circuit board; and a second line and a third line branched from a rear stage of the first line and disposed on the printed circuit board. The second line is configured to set impedance for the selected signal frequency or a double-wave frequency of the selected signal frequency.

### CROSS-REFERENCE TO RELATED APPLICATIONS

This application claims the benefit under 35 USC 119(a) of Japanese Patent Application No. 2016-231488 filed on Nov. 29, 2016 in the Japanese Patent Office and Korean Patent Application No. 10-2017-0150546 filed on Nov. 13, 2017 in Korean Intellectual Property Office, the entire disclosures of which are incorporated herein by reference for all purposes.

### BACKGROUND

### 1. Field

The following description relates to radio frequency power amplifier and a wireless communications device.

### 2. Description of Related Art

A portable communications device such as a portable telephone, a smartphone, or a tablet terminal normally performs communications with a base station, which is a relay device, when wireless communications are performed between communications devices. Typically, the communications device performs communications while adjusting the transmission power and reception sensitivity of a radio frequency signal, according to a distance from a base station.

In addition, in accordance with the rapid growth in the use of portable communications devices, demand for radio frequency power amplifiers that amplify signals within the microwave band has increased. As such, as the demand for radio frequency power amplifiers increases, demand for operating radio frequency power amplifiers at a low voltage, increased efficiency of the radio frequency power amplifiers and reductions in the size and weight of the radio frequency power amplifiers are further increased. Further, a radio frequency power amplifier for achieving high efficiency is implemented by setting load impedance so that both the power and the efficiency of the radio frequency power amplifier are maximized with respect to an output of a fundamental wave frequency of a signal of a transistor to be used. That is, a state of power matching and efficiency matching is achieved by the radio frequency power amplifier.

It is desirable to further improve the efficiency of a radio frequency power amplifier. However, if components and configurations implemented to provide such improved efficiency result in an increase in a size of the radio frequency power amplifier, it may be difficult to implement the radio frequency power amplifier in a portable telephone, which requires minimization. It is therefore desirable to further improve the efficiency of a radio frequency power amplifier in a wireless communications device while reducing a size of the radio frequency power amplifier.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a radio frequency power amplifier includes: a transistor configured to amplify a signal at a selected signal frequency; a first line connected to an output of the transistor and disposed on a printed circuit board; and a second line and a third line branched from a rear stage of the first line and disposed on the printed circuit board, wherein the second line is configured to set impedance for the selected signal frequency or a double-wave frequency of the selected signal frequency.

The second line may include a first microstrip line and a capacitor disposed in parallel with the first microstrip line.

Constants of the first microstrip line and the capacitor may be set to resonate at any frequency within a range of 0.8 times to 1.2 times the signal frequency.

An absolute value of a conceptual value of impedance of the second line viewed from a branch point branched into the second line and the third line may be 500 or more at the selected signal frequency, or an absolute value of a real number of the impedance of the second line may be 1000 or more at the selected signal frequency, and the absolute value of the conceptual value of the impedance of the second line may be 250 or less at the double-wave frequency of the selected signal frequency.

The second line may include a second microstrip line connected to a power source potential of the first microstrip line so as to be in series with the first microstrip line.

The constants of the first microstrip line and the second microstrip line may be set to be short circuited at any frequency within a range of 0.7 times to 1.3 times the double-wave frequency of the selected signal frequency.

The third line may include a capacitor in which one terminal is installed. An end portion of the third line may be a signal output.

The transistor may be a heterojunction bipolar transistor on a GaAs substrate.

In another general aspect, a wireless communications device includes a radio frequency power amplifier including a transistor configured to amplify a signal at a selected signal frequency, a first line connected to an output of the transistor and disposed on a printed circuit board, and a second line and a third line branched from a rear stage of the first line and disposed on the printed circuit board, wherein the second line is configured to set impedance for the selected signal frequency or a double-wave frequency of the selected signal frequency.

The wireless communications device may further include: a modulation circuit configured modulate a transmission signal into the signal at the selected frequency, and to output the signal at the selected frequency to the radio frequency power amplifier.

The wireless communications device may further include: a duplexer configured to receive a reception signal from an antenna, and to output the signal at the selected frequency to the radio frequency power amplifier.

The wireless communications device may be a portable telephone.

Other features and aspects will be apparent from the following detailed description, the drawings, and the claims.

### BRIEF DESCRIPTION OF DRAWINGS

FIG. 1 is a view illustrating a configuration of a radio frequency power amplifier (power amp).

FIG. 2 is a view of impedance in a third-harmonic frequency, illustrated on the Smith chart, in the radio frequency power amplifier illustrated in FIG. 1.

FIG. 3 is a view of impedance in a second-harmonic frequency, illustrated on the Smith chart, in the radio frequency power amplifier illustrated in FIG. 1.

FIG. 4 is a view of impedance in a signal frequency, illustrated on the Smith chart, in the radio frequency power amplifier illustrated in FIG. 1.

FIG. 5 is a view illustrating a configuration of a radio frequency power amplifier, according to an embodiment.

FIG. 6 is a view illustrating a branch path from a node N12 to VDD11 in FIG. 5.

FIG. 7 is a view of impedance Z, illustrated on the Smith chart, when viewing VDD11 from the node N12 in FIG. 5.

FIG. 8 is a view of impedance of a second-harmonic frequency, illustrated on the Smith chart, in the radio frequency power amplifier illustrated in FIG. 5.

FIG. 9 is a view of impedance in a signal frequency, illustrated on the Smith chart, in the radio frequency power amplifier illustrated in FIG. 5.

FIG. 10 is a view illustrating a configuration example of a wireless communications device including the radio frequency power amplifier of FIG. 5, according to an embodiment.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” “coupled to,” “over,” or “covering” another element, it may be directly “on,” “connected to,” “coupled to,” “over,” or “covering” the other element, or there may be one or more other elements intervening therebetween. In contrast, when an element is described as being “directly on,” “directly connected to,” “directly coupled to,” “directly over,” or “directly covering” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

The features of the examples described herein may be combined in various ways as will be apparent after an understanding of the disclosure of this application. Further, although the examples described herein have a variety of configurations, other configurations are possible as will be apparent after an understanding of the disclosure of this application.

Before describing embodiments, of this disclosure, a background of this disclosure will be described.

A technology of implementing a high efficiency radio frequency power amplifier (power amp) by properly adjusting the load impedance of a harmonic frequency including a fundamental wave is disclosed in, for example, T. Yao et al., “Frequency Characteristic of Power Efficiency for 10 W/30 W-Class 2 GHz Band GaN HEMT Amplifiers with Harmonic Reactive Terminations” (Yao). In Yao, it is described that when load impedance ZI in a harmonic frequency such as a double-wave or a triple-wave for the signal frequency is R+jX[Ω], power consumption may be 0 W (reactive) and high efficiency of the power amplifier may be achieved by setting R=0 and moving phases of a current and a voltage in the harmonic frequency, which is mainly generated from a transistor, to 90°. Meanwhile, when R=0, the load impedance may be located on a circumference of the Smith chart. Further, since an optimal X at which the efficiency is maximized generally depends on characteristics or a bias voltage of the transistor, a value of the optimal X may be confirmed by using a load pull, similarly to the load impedance of the signal frequency.

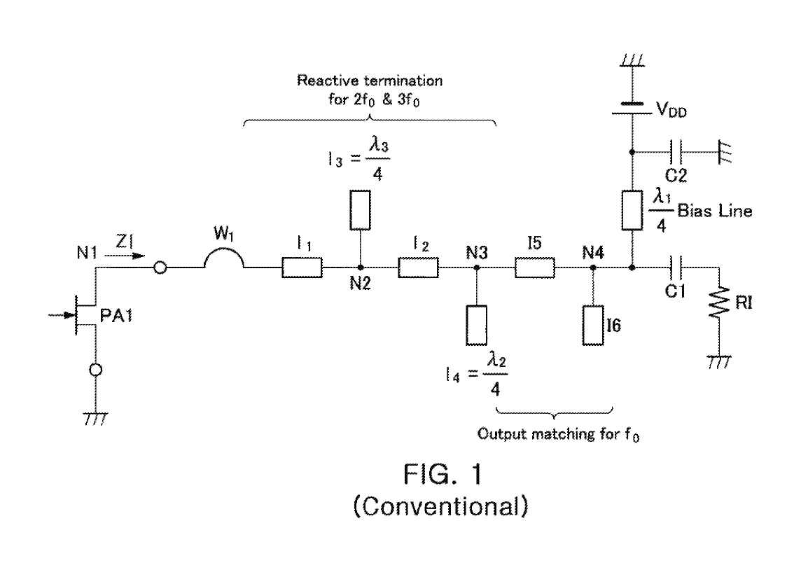

FIG. 1 is a view illustrating a configuration of the radio frequency power amplifier (power amp) disclosed in Yao. A configuration of a rear stage of a transistor that amplifies power is illustrated in FIG. 1.

In FIG. 1, the configuration of the rear stage of the transistor includes a transistor PA1 of the power amplifier, a bonding wire W1 coupling the transistor PA1 to a line on a substrate, microstrip lines l1 to l6 and a ¼ wavelength (λ) bias line of the fundamental wave frequency which are formed on a substrate, and capacitors C1 and C2. A method of making the load impedance ZI in harmonic frequencies (second and third) reactive will be described using the above-mentioned components.

First, a method of making the third-harmonic frequency reactive will be described. In order to make the third-harmonic frequency reactive, a length of the microstrip line l3 is set to an open stub ¼ of a wavelength of the third-harmonic frequency. By setting the length of the microstrip line l3 as described above, impedance when the microstrip line l3 is viewed from a node N2 is short circuited. In addition, by adjusting the lengths of the microstrip line l1 and the bonding wire W1 from the node N2 to the node N1, the optimal X in the third-harmonic frequency is set.

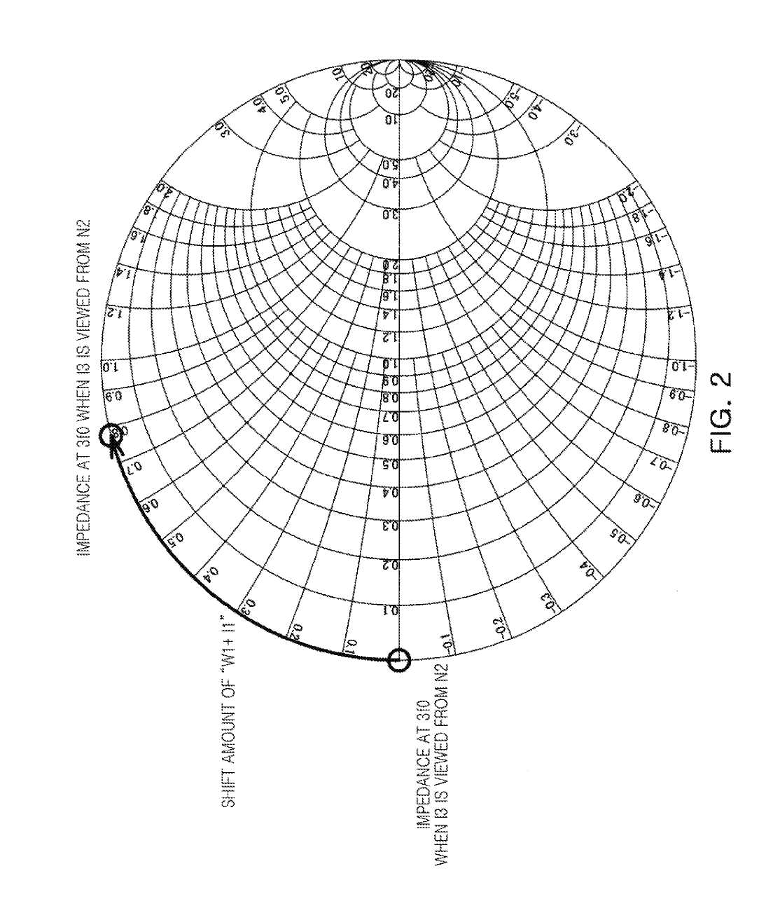

FIG. 2 is a view of impedance in a third-harmonic frequency, illustrated on the Smith chart, in the radio frequency power amplifier illustrated in FIG. 1. In a case in which the length of the microstrip line l3 is properly set, the impedance when the microstrip line l3 is viewed from the node N2 is the short circuit (i.e., is located on a circumference of the Smith chart). In addition, according to a shift amount (adjustment of length) of the microstrip line l1 and the bonding wire W1, the impedance in the third-harmonic frequency is displayed on the circumference of the Smith chart.

Next, a method of making the second-harmonic frequency reactive will be described. In order to make the second-harmonic frequency reactive, a length of the microstrip line l4 is set to an open stub ¼ of a wavelength of the second-harmonic frequency. By setting the length of the microstrip line l4 as described above, impedance when the microstrip line l4 is viewed from a node N3 is short circuited and, by adjusting the length of the microstrip line l2 from the node N3 to the node N2, the optimal X in the second-harmonic frequency is set.

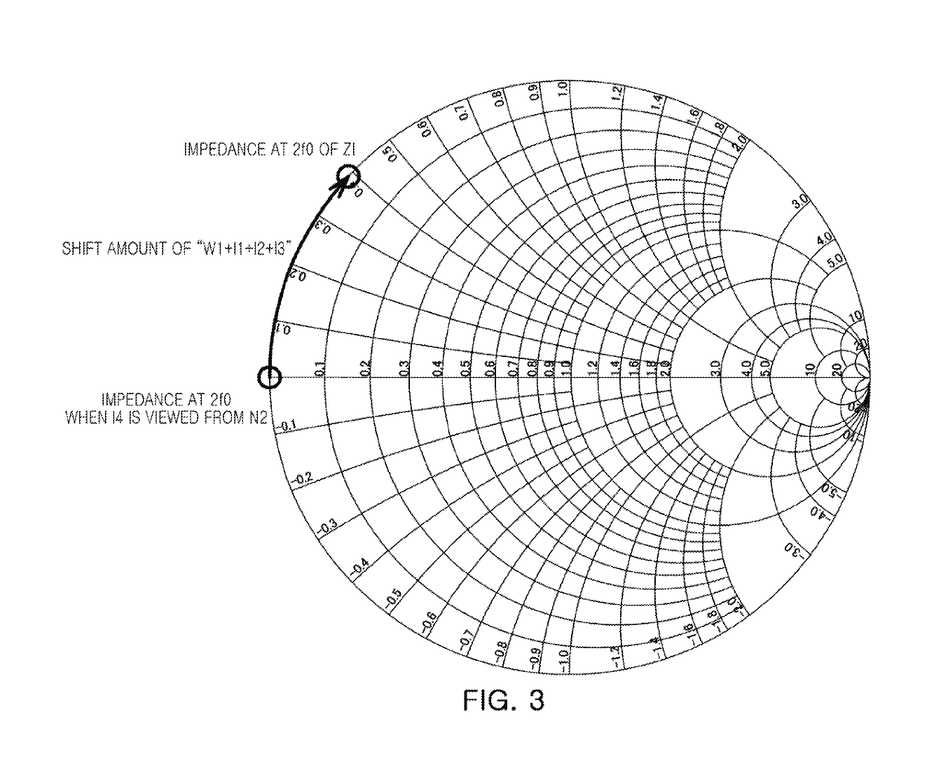

FIG. 3 is a view of impedance in a second-harmonic frequency, illustrated on the Smith chart, in the radio frequency power amplifier illustrated in FIG. 1. In a case in which the length of the microstrip line l4 is properly set, the impedance when the microstrip line l4 is viewed from the node N3 is the short circuit (i.e., is located on a circumference of the Smith chart). In addition, according to a shift amount of the microstrip lines l1 to l3 and the bonding wire W1, the impedance in the second-harmonic frequency is displayed on the circumference of the Smith chart.

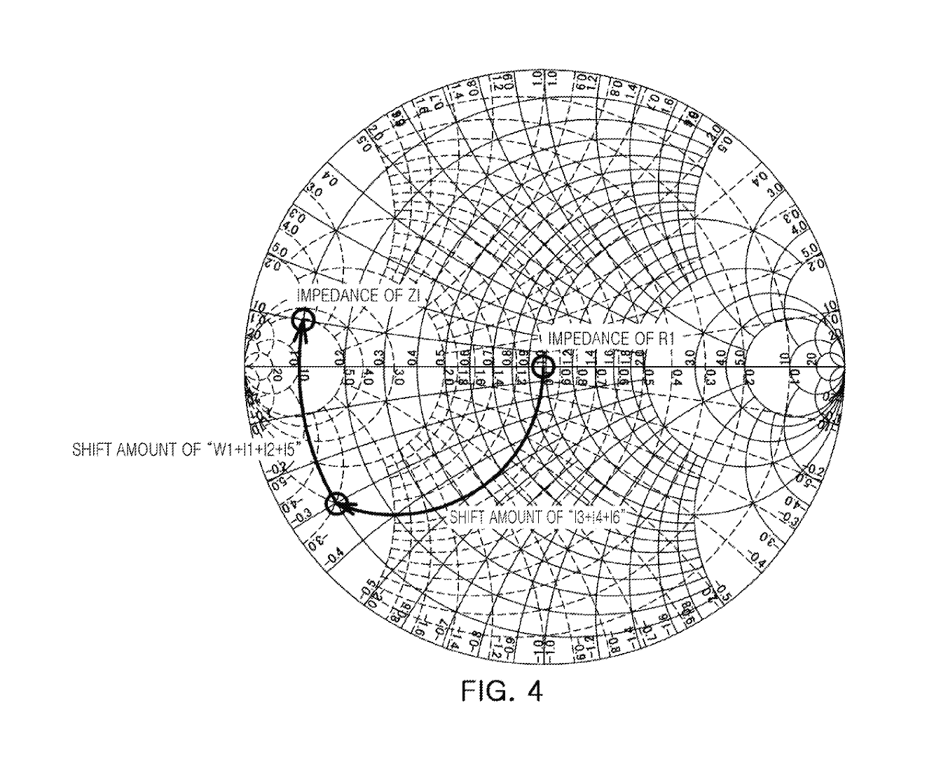

Finally, an optimization of load impedance of a signal frequency will be described. The load impedance of the signal frequency is set to the optimal impedance which is confirmed by the load pull by adjusting the microstrip lines l5 and l6. FIG. 4 is a view of impedance in a signal frequency, illustrated on the Smith chart, in the radio frequency power amplifier illustrated in FIG. 1.

The radio frequency power amplifier illustrated in FIG. 1 sets the optimal load impedances of the fundamental wave, the double-wave, and the triple-wave and implements a high efficiency power amp, according to the setting of the lengths of the microstrip lines, or the like.

However, each of the microstrip lines in the radio frequency power amplifier illustrated in FIG. 1 may have a substantial size as a component. For example, in a frequency of about 2 GHz used in a portable telephone, in a case in which a dielectric constant of a printed circuit board (PCB) is 4, when a wavelength shortening rate is considered, a length of a ¼ wavelength bias line may be about 1.9 cm and the lengths of the microstrip lines l3 and l4 may be ½ and ⅓ of the length of the ¼ wavelength bias line, respectively. It is therefore very difficult to apply the radio frequency power amplifier illustrated in FIG. 1 to a portable telephone that requires miniaturization.

Accordingly, the inventors of this disclosure have conducted extensive studies into a radio frequency power amplifier capable of setting load impedance of a harmonic frequency in addition to a fundamental wave so that an efficiency of the radio frequency power amplifier is maximized while a size of the radio frequency power amplifier is reduced in consideration of the above-mentioned description. As a result, the inventors of this disclosure have devised a radio frequency power amplifier capable of setting load impedance of a harmonic frequency in addition to a fundamental wave so that an efficiency of the radio frequency power amplifier is maximized while reducing a size of the radio frequency power amplifier, as described below.

Next, embodiments of this disclosure will be described in detail.

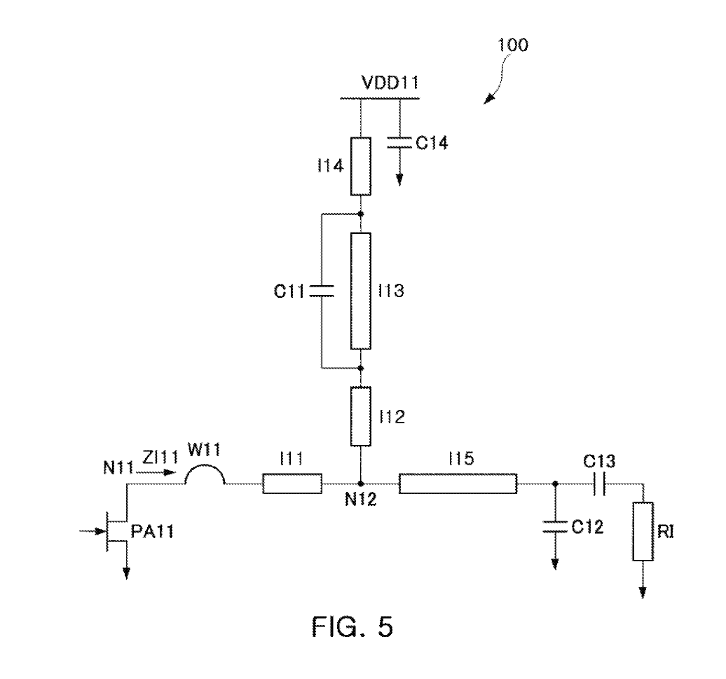

FIG. 5 is a view illustrating a configuration of a radio frequency power amplifier 100, according to an embodiment.

The radio frequency power amplifier 100 includes a transistor PA11 provided on an integrated circuit and that amplifies power of a signal of a predetermined signal frequency, a bonding wire W11 coupling the integrated circuit with a line on a substrate, microstrip lines l11 to l15 formed on the substrate, and capacitors C11 to C14.

The radio frequency power amplifier 100 operates, for example, in a range in which the signal frequency is from 700 MHz to 950 MHz, or from 1200 MHz to 3800 MHz. The transistor PA11 is, for example, a heterojunction bipolar transistor on a GaAs substrate. As an example, a size of an emitter of the transistor PA11 is 1500 μm² to 5000 μm².

In the radio frequency power amplifier 100, in a harmonic frequency, particularly, a second-harmonic frequency that strongly affects efficiency, a method for making load impedance ZI11 of the transistor PA11 reactive will be described.

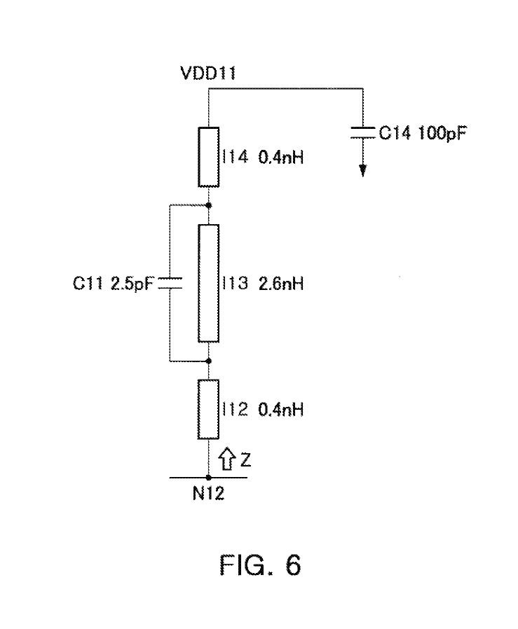

FIG. 6 is a view illustrating a branch path from a node N12 to a power source VDD11 that applies a bias voltage in FIG. 5. In the branch path from the node N12 to the power source VDD11, for example, in a case in which a signal frequency f0 is 2 GHz, the microstrip lines l12 to l14 may be regarded as inductors and are designed to constants as illustrated in FIG. 6, for example. The capacitance of the capacitor C11 and the constant of the microstrip line l13 may be values resonating substantially at a signal frequency f0. The capacitance of the capacitor C11 and the constant of the microstrip line l13 may be the values resonating substantially at the signal frequency f0, but may also be values resonating at any one of frequencies in a range of 0.8 times to 1.2 times the signal frequency f0.

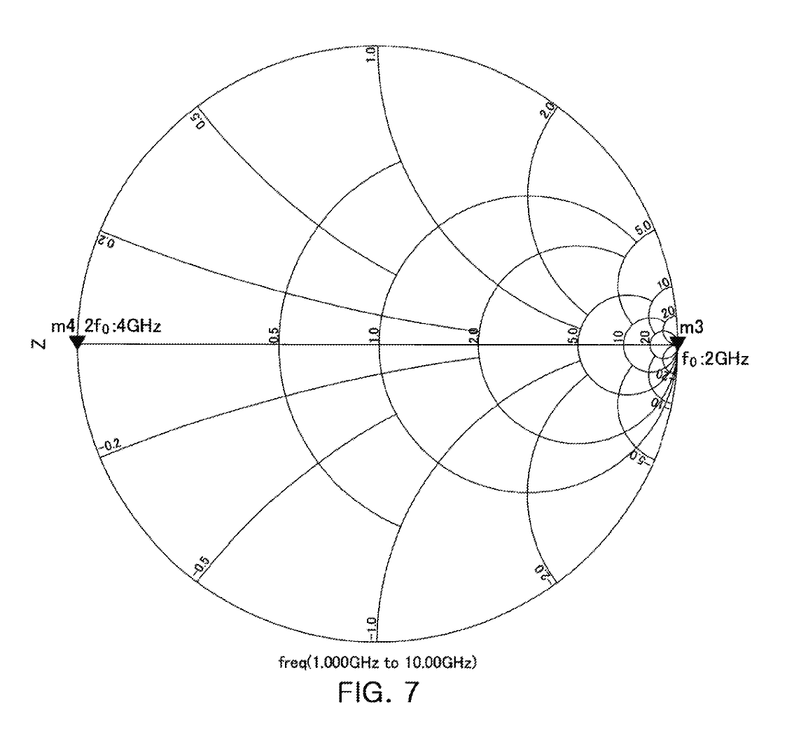

FIG. 7 is a view of impedance Z of a double-wave frequency, illustrated on the Smith chart, when viewing the power source VDD11 from the node N12 in FIG. 5. The impedance Z of the double-wave frequency when the power source VDD11 is viewed from the node N12 is as illustrated on the Smith chart in FIG. 7. The microstrip lines l12 to l14 and the constants of the capacitors C11 and C14 are set to be resonant substantially at the signal frequency f0 by the microstrip line l13 and the capacitor C11, and the microstrip line l13 and the microstrip line l14 also adjust a double-wave frequency 2f0 to be short circuited. As a result, as illustrated in FIG. 7, the impedance Z becomes an open circuit (choke) at the signal frequency f0 and is short circuited at the double-wave frequency 2f0. The constants of the microstrip line l13 and the microstrip line l14 a values which are short circuited at the double-wave frequency 2f0, but may also be values that are short circuited at any frequency within a range of 0.7 times to 1.3 times the double-wave frequency 2f0.

The microstrip lines l12 to l14 and the constants of the capacitors C11 and C14 may be adjusted so that an absolute value of a conceptual value of the impedance when the power source VDD11 is viewed from the node N12 is 500 or more at the signal frequency, or an absolute value of a real number of the impedance when the power source VDD11 is viewed from the node N12 is 1000 or more at the signal frequency.

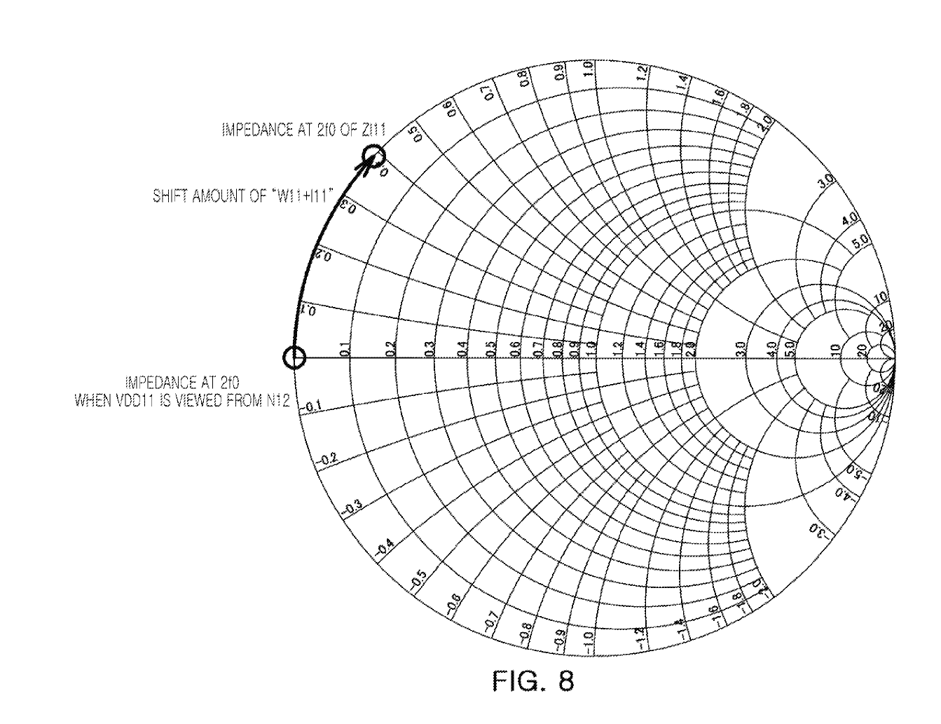

FIG. 8 is a view of impedance of a second-harmonic frequency in the radio frequency power amplifier 100, illustrated on the Smith chart. By adjusting the lengths of the microstrip line l11 and the bonding wire W11, the optimal X in the second-harmonic frequency which is confirmed by the load pull are set as illustrated in FIG. 8. At the same time, by distributing the bias voltage from VDD11, a function of the ¼ wavelength bias line illustrated in FIG. 1 is also performed. That is, the branch path from the node N12 to the power source VDD11 of FIG. 6 replaces the ¼ wavelength bias line and the microstrip line l4 in FIG. 1.

The bonding wire W11 and the microstrip line l11 may be adjusted so that the absolute value of the conceptual value of the second-harmonic frequency is 250 or less.

In a case in which the microstrip lines l12 to l14 having the constants illustrated in FIG. 6 are mounted on the printed circuit board (PCB), when a dielectric constant is 4 and a thickness of the PCB is 0.3 mm, the microstrip line l13 may have a length of 5.4 mm and a width of 0.13 mm and the microstrip lines l12 and l14 may have a length of 0.45 mm and a width of 0.13 mm. Further, the capacitors C11 and C14 may be implemented as a surface mounted component having an area of 0.4 mm×0.2 mm or 0.6 mm×0.3 mm on a PCB plane. Accordingly, a size of the areas of the microstrip lines l12 to l14 may be reduced by ⅓ or more in comparison to a size of the areas of the ¼ wavelength bias line and the microstrip line l4 in FIG. 1.

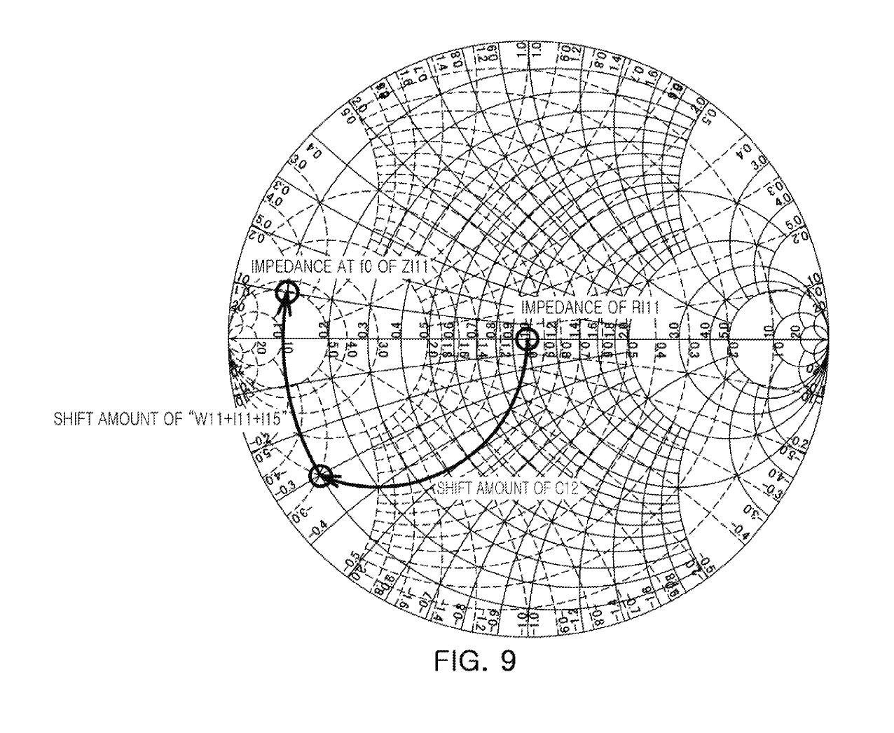

FIG. 9 is a view of impedance in a signal frequency, illustrated on the Smith chart, in the radio frequency power amplifier 100. The load impedance of the signal frequency is set to the optimal impedance, which is confirmed by the load pull as illustrated in FIG. 9, by adjusting the constants of the capacitor C12 and the microstrip line l15. In addition, since the capacitor C13 is a capacitor having large capacitance for DC cut, the capacitor C13 does not contribute to the load impedance.

The radio frequency power amplifier 100 ignores a presence from the node N12 to the power source VDD11 by setting the impedance at the signal frequency to high impedance at the node N12.

As described above, the radio frequency power amplifier 100 sets the load impedance of the harmonic frequency in addition to the fundamental wave so that the efficiency of the radio frequency power amplifier 100 is maximized while reducing the size of the radio frequency power amplifier 100. The radio frequency power amplifier 100 may contribute to miniaturization of a wireless communications device itself or a circuit mounted on a wireless communications device by applying the radio frequency power amplifier 100 to a portable telephone that requires the miniaturization of the circuit or the device itself, and other wireless communications devices.

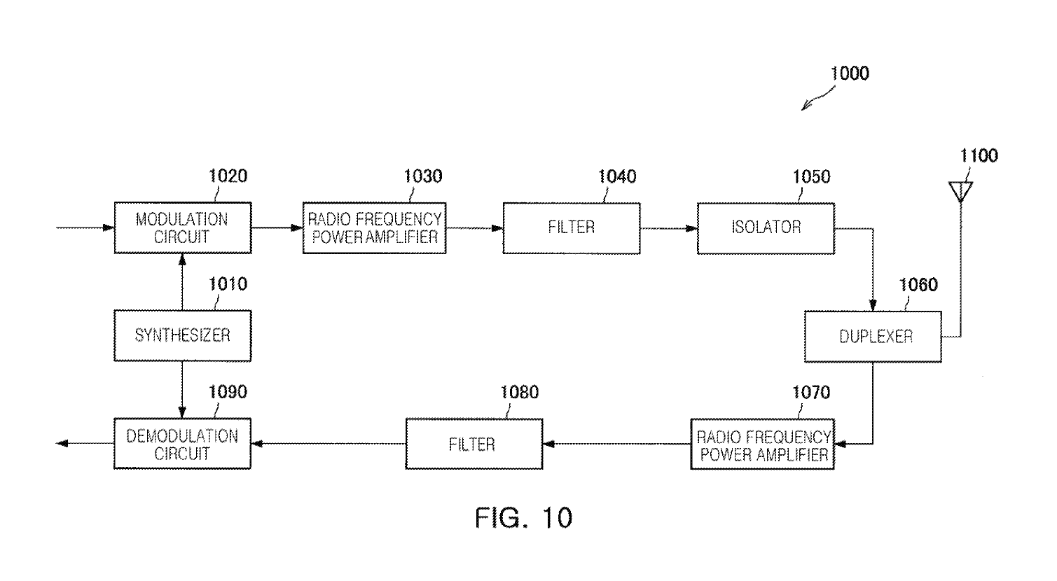

FIG. 10 is a view illustrating a configuration example of a wireless communications device 1000 including the radio frequency power amplifier 100, according to an embodiment.

Referring to FIG. 10, the wireless communications device 1000 includes a synthesizer 1010, a modulation circuit 1020, radio frequency power amplifiers 1030 and 1070, filters 1040 and 1080, an isolator 1050, a duplexer 1060, a demodulation circuit 1090, and an antenna 1100. The radio frequency power amplifiers 1030 and 1070 are, for example, the same as the radio frequency power amplifier 100.

The synthesizer 1010 outputs a signal used to modulate a transmission signal in the modulation circuit 1020 or demodulates a reception signal in the demodulation circuit 1090. The modulation circuit 1020 converts the supplied transmission signal into a transmission signal having a predetermined transmission frequency. The radio frequency power amplifier 1030 amplifies the output signal of the modulation circuit 1020. The filter 1040 is, for example, a band pass filter and extracts a signal of a transmission wave band from the radio frequency signal amplified by the radio frequency power amplifier 1030. The isolator 1050 supplies the output signal of the filter 1040 to the duplexer 1060 in one direction.

The duplexer 1060 has three terminals, that is, a terminal connected to an output terminal of the isolator 1050, a terminal connected to an input terminal of the radio frequency power amplifier 1070, and a terminal connected to the antenna 1100.

The radio frequency power amplifier 1070 amplifies the signal received by the antenna 110 and output from the duplexer 1060. The filter 1080 is, for example, a band pass filter and extracts a signal of a transmission wave band from the output signal of the radio frequency power amplifier 1070. The demodulation circuit 1090 demodulates the signal extracted from the filter 1080 by mixing the signal extracted from the filter 1080 with a local oscillating signal supplied from the synthesizer 1010.

A wireless communications device including the radio frequency power amplifier 100 is not limited to the above-mentioned example. Wireless communications devices other than the wireless communications device 1000 illustrated in FIG. 10 may be applied as long as the wireless communications devices may use the radio frequency power amplifier to amplify a microwave band signal. The wireless communications device including radio frequency power amplifier 100 may operate at a low voltage, increase efficiency, and reduce size and weight.

As described above, according to the embodiments disclosed herein, in an output matching circuit of a power amplifier, a small capacitor of about several pF is added to an output bias voltage line and a parallel resonance circuit for a signal frequency is formed, whereby the second-harmonic frequency is set to a high efficiency impedance while distributing an output bias voltage having a very low level.

For example, the radio frequency power amplifier 100 described above has the configuration in which the impedances of the fundamental wave and double-wave frequencies become the optimal impedance, but a ¼ wavelength plate as illustrated in FIG. 1 or a new resonance circuit may also be added between the bonding wire W11 and the node N12 so that the impedance of the triple-wave frequency becomes the optimal impedance.

As set forth above, according to the embodiments disclosed herein, a new and improved radio frequency power amplifier and a wireless communications device capable of setting the load impedance of the harmonic frequency in addition to the fundamental wave so that the efficiency of the radio frequency power amplifier is maximized while reducing the size of the radio frequency power amplifier may be provided.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A radio frequency power amplifier, comprising:
a transistor configured to amplify a signal at a selected signal frequency;
a first line connected to an output of the transistor and disposed on a printed circuit board; and
a second line and a third line branched from a rear stage of the first line and disposed on the printed circuit board,
wherein the second line is configured to set impedance for the selected signal frequency or a double-wave frequency of the selected signal frequency.

2. The radio frequency power amplifier of claim 1, wherein the second line comprises
a first microstrip line, and
a capacitor disposed in parallel with the first microstrip line.

3. The radio frequency power amplifier of claim 2, wherein constants of the first microstrip line and the capacitor are set to resonate at any frequency within a range of 0.8 times to 1.2 times the signal frequency.

4. The radio frequency power amplifier of claim 3, wherein an absolute value of a conceptual value of impedance of the second line viewed from a branch point branched into the second line and the third line is 500 or more at the selected signal frequency, or an absolute value of a real number of the impedance of the second line is 1000 or more at the selected signal frequency, and the absolute value of the conceptual value of the impedance of the second line is 250 or less at the double-wave frequency of the selected signal frequency.

5. The radio frequency power amplifier of claim 2, wherein the second line comprises a second microstrip line connected to a power source potential of the first microstrip line so as to be in series with the first microstrip line.

6. The radio frequency power amplifier of claim 5, wherein the constants of the first microstrip line and the second microstrip line are set to be short circuited at any frequency within a range of 0.7 times to 1.3 times the double-wave frequency of the selected signal frequency.

7. The radio frequency power amplifier of claim 1, wherein
the third line comprises a capacitor in which one terminal is installed, and
an end portion of the third line is a signal output.

8. The radio frequency power amplifier of claim 1, wherein the transistor comprises a heterojunction bipolar transistor on a GaAs substrate.

9. A wireless communications device, comprising:
a radio frequency power amplifier comprising
a transistor configured to amplify a signal at a selected signal frequency,
a first line connected to an output of the transistor and disposed on a printed circuit board, and
a second line and a third line branched from a rear stage of the first line and disposed on the printed circuit board,
wherein the second line is configured to set impedance for the selected signal frequency or a double-wave frequency of the selected signal frequency.

10. The wireless communications device of claim 9, further comprising:
a modulation circuit configured modulate a transmission signal into the signal at the selected frequency, and to output the signal at the selected frequency to the radio frequency power amplifier.

11. The wireless communications device of claim 9, further comprising:
a duplexer configured to receive a reception signal from an antenna, and to output the signal at the selected frequency to the radio frequency power amplifier.

12. The wireless communications device of claim 9, wherein the wireless communications device is a portable telephone.
